(19) United States
(12) Patent Application Publication
(10) Pub. No.: US 2014/0246068 A1
(43) Pub. Date: Sep. 4, 2014

(54) METAL CONNECTOR PROFILE, SOLAR MODULE AND METHOD FOR ITS MANUFACTURE

(71) Applicants: Hans-Joachim KROKOSZINSKI, Koenigslutter Am Elm (DE); Henrico RUNGE, Farmington Hills, MI (US); Patrick ZERRER, Weinstadt (DE); Anika PRIESSNER, Iserlohn (DE)

(72) Inventors: Hans-Joachim KROKOSZINSKI, Koenigslutter Am Elm (DE); Henrico RUNGE, Farmington Hills, MI (US); Patrick ZERRER, Weinstadt (DE); Anika PRIESSNER, Iserlohn (DE)

(73) Assignee: ROBERT BOSCH GMBH, Stuttgart (DE)

(21) Appl. No.: 14/196,693

(22) Filed: Mar. 4, 2014

(30) Foreign Application Priority Data
Mar. 4, 2013 (DE) 10 2013 203 638.8

(51) Int. Cl. H01L 31/05

(52) U.S. Cl. CPC H01L 31/0508
USPC 136/244; 136/252; 438/73

(57) ABSTRACT

A metal connector profile for the electrical connection and interconnection of back-contact solar cells is described. In addition, a solar module as well as a method for manufacturing such a solar module are described as well.

### FIELD OF THE INVENTION

The present invention relates to a metal connector profile for the electrical connection and interconnection of back-contact solar cells. In addition, it relates to a solar module as well as a method for manufacturing such a solar module.

### BACKGROUND INFORMATION

It is well-known to join solar cells produced from crystalline silicon—whose dimensions are limited because of the restrictions imposed by the manufacturing technology of single-crystal silicon—mechanically and electrically to form larger photovoltaic configurations, what are termed solar modules. In so doing, contact areas for the external contacting of a solar cell are joined to the contact areas of an adjacent solar cell, and initially, series arrangements of a plurality of solar cells, referred to as strings, are formed. Several strings are then combined and interconnected to form a solar module which has at least one connection box for the external connection upon assembling a larger photovoltaic array.

The electrical interconnection of conventional crystalline solar cells to form strings and sometimes also the electrical connectors of a solar module are usually produced from strip-shaped metal connectors, referred to as narrow bands or ribbons, which for the most part are made of copper and are generally joined with material locking to the connection areas of the solar cells by soldering, but occasionally also with the aid of a conductive adhesive. The material for these narrow bands or ribbons is delivered as roll material and during the process of assembling the strings or solar modules, is cut to length according to the conditions of the geometrical configuration.

In order for the solar cells to be shaded as little as possible, connectors having a small width, but instead the greatest height possible are preferred here, high mechanical and thermomechanical stress acting on the cells.

For the same reason, namely, to maximize the surface area effective for the photoelectric energy conversion, various types of what are termed back-contact cells have been developed in recent years, where basically the connection contacts and the interconnections between the individual cells are placed completely on the back sides. As in the case of standard solar cells (also known as H pattern cells), the connection areas of the solar cells are disposed on a type of bus line referred to as busbar.

However, they are very narrow and are separated by only a thin trench from the region of adjacent polarity. The width of the metal cell connectors applied on the back side is likewise limited by the restricted dimensions of the busbars, so that a relatively great height must be selected in order to attain the current-carrying capacities required. This is disadvantageous for the encapsulation and later handling of the modules. Incidentally, to avoid short circuits, the cell is provided with insulating layers, or the busbars must be dimensioned to be correspondingly wider in order to compensate for the machine tolerances upon joining and to permit the use of wider cell connectors.

### SUMMARY

The present invention provides a metal cell-connector profile. In addition, a solar module as well as a method for manufacturing such a solar module are described.

The inventors are deliberately turning away from the use of cell connectors of relatively great height or thickness for the interconnection of back-contact solar cells, as well as from concepts which provide a costly insulation of the solar-cell back sides in order to avoid short circuits in the edge area of the busbars. Instead of insulating the critical areas of the cells, the invention includes the idea of providing a partial insulation of the cell connectors. It further includes the idea to already provide this insulation in the starting material of the cell connectors, the metal connector profile provided as roll material. At the same time, the invention includes the idea of utilizing this concept of the partial insulation of the connector surface to increase the profile width beyond the extent permissible for non-insulated back sides of back-contact solar cells. This in turn makes it possible to reduce the height or to increase the width/height ratio, accompanied by the same current-carrying capacity.

In one embodiment of the invention, the cross-section of the metal connector profile is flatly rectangular, and the short sides of the rectangle as well as adjoining areas of the long sides are covered with the insulating layer. A flatly elliptical cross-sectional form or a flatly rectangular cross-section rounded off on both sides, in each case having insulated lateral edge areas, are usefully possible, as well.

In further embodiments, a central area of at least one surface having a width in the range between 1 mm and 2 mm, especially between 1.2 mm and 1.5 mm, is free of an insulating layer throughout or in sections. The specific portion of the insulated sections of the connector profile is determined in coordination with customary busbar geometries of back-contact cells on one hand, and in view of the conductivity of the profile material and the requisite current-carrying capacity, and the desired profile width ensuing from that on the other hand.

In one development, in the delivery condition, the entire profile surface is covered with the insulating layer. In the case of this development, prior to assembly, a central area of the insulating layer must be removed again in order to expose the surface of the metallic core there, and to permit electrical contacting with the cell terminals. The surface of the metallic core may be exposed throughout in strip-like fashion or perhaps only locally in sections, in doing which, purely mechanical techniques as well as the use of energy-rich radiation coming into consideration, the latter being particularly suitable if the insulating layer is to be removed only locally.

In special geometrical forms of the connector profile, the profile height amounts to 0.3 mm or less, particularly 0.2 mm or less, and the profile width lies in the range between 1.5 mm and 15 mm, especially between 5 mm and 10 mm. The dimensions are determined in concrete terms according to the criteria/standards addressed above, and in principle, the invention is also able to be realized outside of the range limits indicated here.

In embodiments expediently usable in practice in terms of material, the metallic part is made predominantly of copper or a copper alloy or aluminum or an aluminum alloy. In this connection, from case to case, copper or an alloy based on copper may be preferred because of the high conductivity, and aluminum or an alloy based on aluminum may be preferred because of the lower costs. At least one free surface of the metallic part may have a silver coating, especially produced galvanically. Such a coating or a similar coating (possibly also produced on the basis of an alloy) may advantageously improve the soldering capability and/or may reduce the contact resistance at the solar-cell terminals.

In further embodiments, the insulating layer has an insulating-varnish coating or synthetic-resin coating. In this case, in general, commercial insulating varnishes or synthetic resins proven in electrical engineering are usable without special restrictions. Alternatively or possibly also in combination with an insulating-varnish coating or synthetic-resin coating, the insulating layer may have an oxide coating or ceramic coating, in the case of Al connector profiles, for example, made of galvanically reinforced aluminum oxide.

From the standpoint of process engineering, basically there are no important deviations from known processes of cell-joining techniques, and conventional Tabber Stringer technologies and systems are usable to a great extent, soldering, adhesive bonding or bonding or perhaps other techniques being possible as joining techniques, and a specific technique being selected as a function of the material (metal and insulating layer) of the connector profile.

As far as the production of the metal connector profiles themselves is concerned, it may be carried out as a roll-to-roll process with partial dipping into the material, thus resulting in a very cost-effective process suitable for mass production.

Owing to the present invention, especially IBC cells are able to be produced without costly back-side insulation. On the other hand, the disadvantages of cell connectors mentioned, having relatively small width and instead relatively great height are avoided. At the same time, the connector profile is able to be protected from corrosion by the varnish layer or other insulating layer. Due to the protection against corrosion, an interconnect layer, protected by noble metals, on the surface may be reduced above all in the case of connectors for conductive adhesives (in this instance, first of all the insulation medium is applied, and after that, for example, silver-plated).

In view of the fact that for certain practical applications, a solar-module appearance which optically, is as homogeneous as possible is desired or even necessary, by suitable coloration of the insulating layer in coordination with the color of the solar-cell surfaces, the connector profiles of the present invention offer the possibility of attaining a considerable improvement. This succeeds particularly well in the case of connector profiles covered completely or almost completely with an insulating layer, thus, especially in the embodiment of the invention mentioned above, where prior to assembly, only the cell-connector surface areas absolutely necessary for the cell contacting are exposed.

### BRIEF DESCRIPTION OF THE DRAWINGS

FIG. 1A to 1F show exemplary embodiments of metal connector profiles according to the present invention in cross-section.

FIGS. 2 and 2A respectively, show a rear view of a solar-cell back side contacted with metal connector profiles according to the present invention, and a sectional representation from it.

FIG. 3 shows a perspective representation of an exemplary metal connector profile in usage condition prior to the assembly operation.

### DETAILED DESCRIPTION

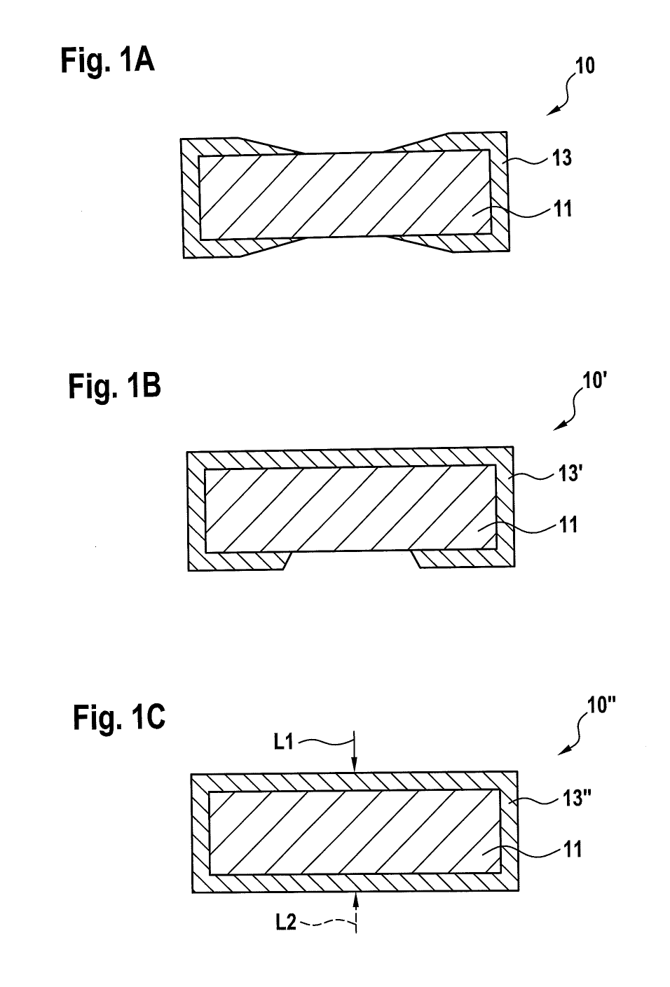

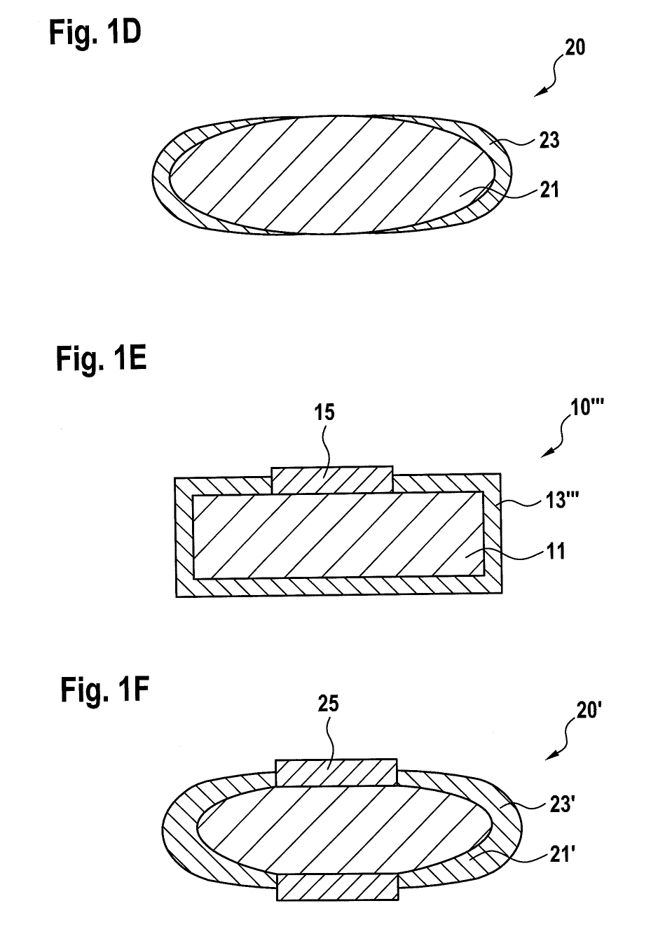

FIG. 1A through 1F show examples of geometrical configurations of a metal connector profile according to the present invention as schematic cross-sectional representations. The representations are not to be understood as true to scale, and wide-ranging variation possibilities exist with regard to the width/height ratio, the lateral extension and thickness of the insulating coating and further geometrical details.

FIG. 1A shows a metal connector profile 10 having metal core 11 (made of copper, for instance) which is rectangular in cross-section, and having an insulating coating 13 covering the two short sides of the rectangle and the adjoining areas of the long sides, but leaving the middle areas of the long sides free.

As a somewhat modified variant, FIG. 1B shows a metal connector profile 10′ having a metal core 11 in the same implementation as in the case of FIG. 1A, which, however, has an insulating coating that covers the two short sides and one long side of the rectangle completely, and leaves the surface of metal core 11 free only in the middle area of the remaining long side.

As a further modified variant, FIG. 1C illustrates a metal connector profile 10″, which has a metal core 11 corresponding to the previous embodiments and an insulating coating 13″ surrounding it completely. A first laser irradiation is symbolized in the figure by arrow L1 and an optional second laser irradiation is symbolized by dashed arrow L2. This is intended to illustrate that the middle area of one or both profile surfaces may be freed of the closed insulating layer by laser ablation, and thus prepared for contacting of a solar cell.

FIG. 1E shows a further metal connector profile 10″′ which has an especially thin insulating layer (for instance, an oxide layer) 13″′ on metal core 11, the insulating layer being omitted in the central area of one of the long sides of the profile cross-section. A metallic coating 15 is applied there galvanically, for instance, to improve the soldering capability of the connector profile.

FIG. 1D shows another metal connector profile 20 which has a flatly elliptical metal core 21 and a partial insulating coating 23 that covers the two edge areas of the metal core but leaves the central areas of the metal core open.

FIG. 1F shows another metal connector profile 20′ having a metal core 21′ which is essentially rectangular but rounded off in semicircular fashion at both edges. Here, as well, an insulating coating 23′ is provided on both edge areas, thus, the semicircular sections of the profile cross-section, while the middle area of both profile surfaces has no insulating coating. Instead, a layer 25 is provided here (on both sides), which reduces the contact resistance and, for example, may be formed by rolling a highly conductive thin metal strip onto thicker metallic core 21′.

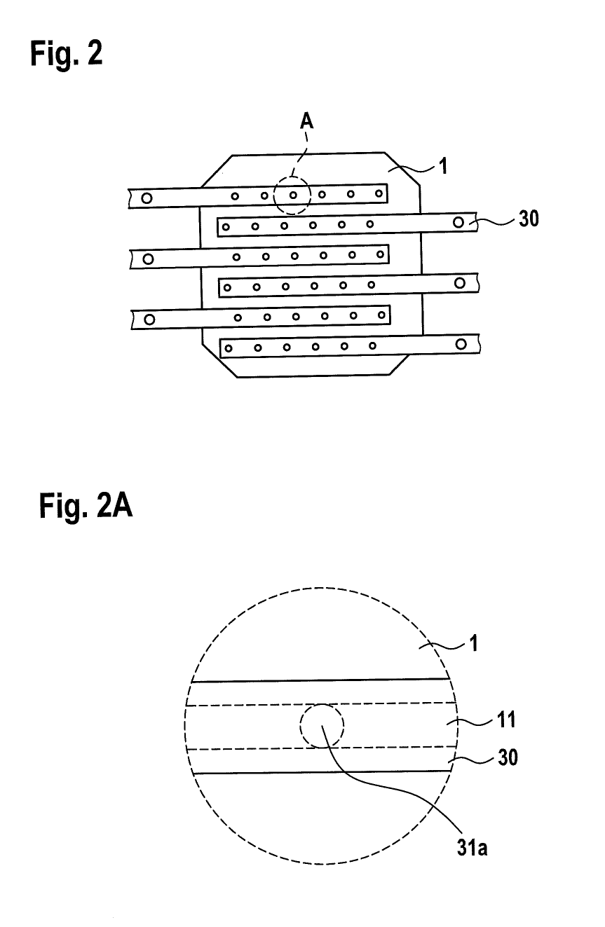

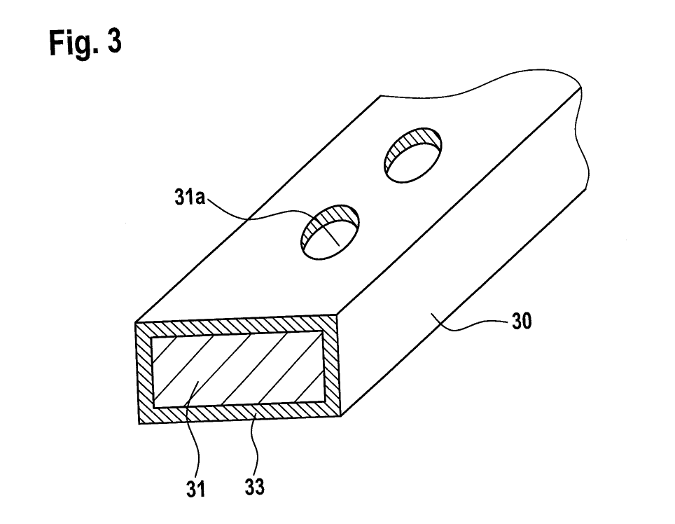

FIGS. 2 and 2A, respectively, show, in sketch-like fashion, a rear view of a back-contact solar cell 1 having applied connector profiles 30 as illustrated in FIG. 1B, and an enlarged section A from it. Connector profiles 30 used here are shown separately in FIG. 3 in a perspective representation. They are connectors covered with an essentially closed insulating layer 33 and having a metal core 31 with a rectangular cross-section, in which the insulation is removed only locally in central sections of one of the two profile surfaces, so that metallic contact points 31a are exposed there. FIG. 2A shows a section of a busbar 11 lying below cell connector 30, and it can be seen that the width of contact point 31 a corresponds to the width of busbar 11. Since all surfaces of the connector that are outside of the contact points are insulated, short circuits are reliably prevented, and at the same time, the connector surfaces are protected from corrosion.

Further refinements and specific embodiments of the method and the device, described here only by way of example, are obtained within the scope of normal expert activity.

What is claimed is:

1. A metal connector profile for an electrical connection and interconnection of back-contact solar cells, comprising:
a structure having a profile width and a profile height, wherein the profile width amounts to at least quadruple the profile height; and
an insulating layer covering at least both lateral edge areas.

2. The metal connector profile as recited in claim 1, wherein a cross-section is flatly rectangular, and short sides of rectangle as well as adjoining areas of long sides are covered with the insulating layer.

3. The metal connector profile as recited in claim 1, wherein a central area of at least one surface having a width in a range between 1 mm and 2 mm is free of the insulating layer throughout or in sections.

4. The metal connector profile as recited in claim 1, wherein in a delivery condition, an entire profile surface is covered with the insulating layer.

5. The metal connector profile as recited in claim 1, wherein the profile height is 0.3 mm or less, and wherein the profile width lies in the range between 1.5 mm and 15 mm.

6. The metal connector profile as recited in claim 1, wherein a metallic part of the metal connector profile is made predominantly of one of copper, a copper alloy, aluminum, and an aluminum alloy.

7. The metal connector profile as recited in claim 1, wherein at least one free surface of the metallic part of the metal connector profile has a conductive layer.

8. The metal connector profile as recited in claim 1, wherein the insulating layer has one of an insulating-varnish coating and a synthetic-resin coating.

9. The metal connector profile as recited in claim 1, wherein the insulating layer has one of an oxide coating and a ceramic coating.

10. A solar module, comprising:
a plurality of back-side-contact cells interconnected by metal cell connectors to form strings, the metal cell connectors being formed from a metal connector profile including:
a structure having a profile width and a profile height, wherein the profile width amounts to at least quadruple the profile height, and
an insulating layer covering at least both lateral edge areas, wherein a surface section, free of the insulating layer, of each metal cell connector is joined mechanically and electrically to a connection area of the solar cells.

11. The solar module as recited in claim 10, wherein the connection area includes a busbar.

12. A method for producing a solar module including a plurality of back-side-contact cells interconnected by metal cell connectors to form strings, the metal cell connectors being formed from a metal connector profile including a structure having a profile width and a profile height, wherein the profile width amounts to at least quadruple the profile height, and an insulating layer covering at least both lateral edge areas, wherein a surface section, free of the insulating layer, of each metal cell connector is joined mechanically and electrically to a connection area of the solar cells, the method comprising:
providing the metal cell connectors having entire profile surfaces covered with the insulating layer; and
removing the insulating layer at least in sections in a central area of at least one profile surface prior to the mechanical and electrical joining to the respective connection contacts of the solar cells.

13. The method as recited in claim 12, wherein the insulating layer is removed in the central area using energy-rich radiation.

14. The method as recited in claim 13, wherein the energy-rich radiation includes laser ablation.

15. The method as recited in claim 12, wherein the insulating layer is removed locally only in predetermined sections of the central area.

16. The metal connector profile as recited in claim 1, wherein the metal connector profile is for forming a solar-cell string.

17. The metal connector profile as recited in claim 3, wherein the range is between 1.2 mm and 1.5 mm.

18. The metal connector profile as recited in claim 1, wherein the profile height is 0.2 mm or less, and wherein the profile width lies in the range between 5 mm and 10 mm.

19. The metal connector profile as recited in claim 7, wherein the conductive layer is produced galvanically.
